(19) United States
(12) Patent Application Publication
(10) Pub. No.: US 2004/0075989 A1
(43) Pub. Date: Apr. 22, 2004

(54) Electrical device with a water-tight housing and method of making same

(76) Inventor: Ka Chai Wong, Hong Kong (CN)

Correspondence Address: BURNS, DOANE, SWECKER & MATHIS, L.L.P., P.O. Box 1404, Alexandria, VA, 22313-1404, US

(21) Appl. No.: 10/273,164

(22) Filed: Oct. 18, 2002

(51) Int. Cl. H05K 5/00; H05K 5/04; H05K 5/06

(52) U.S. Cl. 361/752

(57) ABSTRACT

An electrical device including a main hollow housing inside which there are housed a plurality of electrical connections, the main housing includes at least a first and a second housing members which together form a hollow space for accommodating the connections, the first and second housing members being sealed and connected along their corresponding edges with a moulded layer of non-permeable thermoplastic material which is adhesive or bondable to the first and second housing of the main housing.

### FIELD OF INVENTION

The present invention relates to electrical devices and, more particularly, to humidity or moisture sensitive electrical devices. More specifically, although of course not solely limiting thereto, this invention relates to power converters, power adapters and other power electronic devices having a power conversion circuitry enclosed within a rigid housing. This invention also relates to methods, process and moulds for making generally water-tight electrical devices.

### BACKGROUND OF THE INVENTION

Electrical or electronic circuits and devices are usually enclosed within a rigid and insulated housing for safety, reliability, durability and various other reasons. For example, for circuits or devices which are vulnerable to moisture, oxidation, corrosion and/or deposit of dust or dirt, it is desirable that the circuits or devices are isolated from the ambient environment by enclosing them in a water-or moisture-tight casing or housing. For electrical devices having connections with high potential differences separated by small distances due to limitation of space, for example, power converters or power adaptors for mobile phone battery charger, moisture leakage into the conversion circuitry may cause short circuit which may lead to fire hazards or damage to other devices or the users. For electronic devices requiring efficient heat dissipation, deposit of dust or oxidation of heat dissipation services may adversely affect the heat dissipation efficiency and may even cause damage to the delicate devices.

To shield delicate circuits or devices from the adverse ambient environment, epoxy resin has been used to encapsulate an integrated circuit. However, epoxy resin is generally heavy and thermally insulative which is not suitable for circuits having heat dissipating elements. U.S. Pat. No. 4,795,857 describes the forming of a waterproof housing by pre-filling the junctions with a plastic insulating gel which becomes adhesively attached to the housing to form a perimeter seal. However, application of an insulating gel, or sealant in general, is usually a tedious and skill sensitive manual operation which is expensive and time consuming.

Many circuitry or devices are enclosed within a rigid plastic housing composed of a top housing member and a bottom housing member which are connected together and sealed by ultrasound welding means. However, it is a well known shortcoming of ultrasonic welding that the bonding may be unstable or uneven. Also, there is a high failure rate of ultrasonic welding at comer positions or abrupt junctions.

Hence, it will be highly desirable if there can be provided electric or electrical or electronic devices with means to enhance water-tightness or moisture-tightness to meet with the specific environmental requirements of certain devices, apparatus or circuitry. It will also be desirable if such means to enhance water-tightness or moisture tightness of electrical or electronic devices, circuitry and apparatus can be provided at low costs, high reliability and high yield rate without unduly complicated manufacturing methods, skills or components. Likewise, it is highly desirable if there can be provided methods, process and tools for making such devices, circuitry and apparatuses with enhanced water- or moisture-tightness which can at least alleviate some of the shortcomings of conventional methods, process and tools.

### OBJECT OF THE INVENTION

It is therefore an object of the present invention to provide electrical devices, circuitry and apparatuses with enhanced water-tightness while at least alleviating some or all of the shortcomings associated with known devices or methods. Preferably, such an objective can be achieved without costly or unduly complicated tools, methods or process to enhance productivity and minimize costs for the benefit of the public. It is also an object of the present invention to provide electrical and/or electrical devices with improved water-tightness or moisture-tightness without adversely affecting their characteristics or performance such as weight, durability and size.

It is a further object of the present invention to provide tools, process and methods for making electrical or electronic devices fulfilling the afore-mentioned requirements. At a minimum, it is an object of the present invention to provide the public with a useful choice of water- or moisture-tight electrical or electronic devices or apparatuses as well as tools, methods and process for making same.

### SUMMARY OF THE INVENTION

Accordingly, there is provided in the first aspect of the present invention an electrical device including a main hollow housing inside which there are housed a plurality of electrical connections, said main housing includes at least a first and a second housing members which together form a hollow space for accommodating said connections, said first and second housing members being sealed and connected along their corresponding edges with a moulded layer of non-permeable thermoplastic material which is adhesive or bondable to said first and second housing of said main housing.

Preferably, said electrical device includes a peripheral groove extending generally along said connected corresponding edges and spanning said first and second housing members is generally formed by co-operation between said first and said second housing members, said peripheral groove being generally filled with said non-permeable thermoplastic material for sealing.

Preferably, said thermoplastic material being a thermoplastic elastomer.

Preferably, said first and second housing members being made of hard thermoplastics.

Preferably, said first and second housing members being made of ABS, polycarbonate or an alloy of ABS and polycarbonate.

Preferably, said thermoplastic material for sealing being made either of Thermoplastic-urethane (TPU) or Thermoplastic Elastomer (TPE).

Preferably, said thermoplastic sealing material being applied on said main housing by injection moulding.

Preferably, said thermoplastic sealing material being applied on said main housing by in-mould or over-mould process.

Preferably, said device further includes a conductive plug extending outwardly from one of said housing members and a cable extending from a junction between said first and said second housing members.

Preferably, said junction between said cable and said main housing is sealed with a moulded layer of thermoplastic material.

Preferably, power supply circuit is connected between said cable and said conductive plug and is housed within said main housing.

Preferably, said power supply circuitry includes a transformer, a rectifying circuit, or a combination of both a transformer and a rectifying circuit.

Preferably, said first and said second housing members are connected by ultrasonic welding before the filling of said non-permeable thermoplastic sealing material along said corresponding edges.

In another aspect, there is provided in the present invention the steps of:-

forming said electrical connections and housing said connections within said main housing,

connecting said first and second housing members,

placing said connected first and second housing members into a mould,

moulding said layer of non-permeable thermoplastic to said corresponding edges of said main housing.

It is a further aspect of the present invention to provide a mould for making an electrical or electronic device with the aforesaid characteristics.

Preferably, said mould being characterized in having a plurality of injection points distributed along locations opposite said corresponding edges.

Preferably, said mould includes a plurality of injection points distributed at locations corresponding and opposite to said corresponding edges of said main housing, each injection step utilizes two injection points on generally diagonally opposite sides of said main housing.

### BRIEF DESCRIPTION OF THE DRAWINGS

Preferred embodiments of the present invention will be explained in further detail below by way of examples and with reference to the accompanying drawings, in which:-

FIG. 1A is a cross-sectional view showing a semi-assembled electrical device of a first preferred embodiment of the present invention including the second housing member of the main housing and a moisture vulnerable electronic circuitry connected between an electric plug and a cable,

FIG. 1B illustrates the semi-assembled electrical device of FIG. 1A with the first housing member connected to the second housing member, thereby enclosing the moisture sensitive circuitry within the main housing,

FIG. 1C shows a cross-sectional view of the electrical device of FIG. 1B with the corresponding edges between the first housing member and the second housing member sealed with a moulded thermoplastic layer,

FIG. 2A is an enlarged view of the circled portion of FIG. 1C with emphasis on the corresponding edges between the first housing member and the second housing member and showing the filling of the thermoplastic sealing material along the corresponding edges,

FIG. 2B is an enlarged view of the circled portion of FIG. 2A showing the corresponding edges between the first housing member and the second housing member with particular emphasis showing the channel or groove spanning the first housing member and the second housing member,

FIG. 3 is a perspective view showing the electrical device of FIG. 1B after the thermoplastic sealing material has been moulded onto the main housing and along the corresponding edges between the first and the second housing members,

FIG. 4 illustrates the placing or insertion of the semi-assembled device of FIG. 1B into a mould in advance of injection moulding by in-moulding or over-moulding process,

FIG. 4B shows the enlarged view of the circled portion of FIG. 4 showing the space between the semi-assembled device and the boundary of the mould which defines the shape of the moulded thermoplastic sealing layer,

FIG. 5 illustrates an example of appropriate distribution of a plurality of injection points to be formed on the mould of FIG. 4 for moulding the thermoplastic sealing layer onto the main housing of the electrical device,

FIG. 6A shows a second preferred embodiment of the present invention including the device of FIG. 1B with the moulding of the thermoplastic elastomer in a second preferred way,

FIG. 6B is an enlarged view of the circled portion of FIG. 6A with particular emphasis on the connecting portion between the first housing member and the second housing member,

FIG. 6C is an enlarged view of the circled portion with solid line with particular emphasis on the regions surrounding the corresponding edges of the first housing member and the second housing member,

FIG. 7 is a perspective view of the device of FIG. 6A,

FIG. 8 is a third preferred embodiment of the present invention showing an ALCI or a GLCI plug with a sealing layer moulded according to the second preferred moulding manner as shown in FIGS. 6A and 7,

FIG. 9 shows the device of FIG. 8 with the thermoplastic elastomeric sealing layer applied according to the first manner of moulding as described with reference to FIG. 1C to FIG. 5,

FIG. 10A is a perspective view showing a fourth preferred embodiment of an electrical device in the form of a non-contact charging station,

FIG. 10B is a cross-sectional view showing the charging station of FIG. 10A, and

FIG. 11 is an enlarged view showing the connecting portion between the circuitry 20 and the electric plug 30 of the first to third embodiments.

### DETAILED DESCRITION OF THE PREFERRED EMBODIMENTS

Referring to the Figures, there is shown an electrical device 1 in the form of a power converter or power adapter for charging the battery of a mobile telephone as an example to assist the illustration of a first preferred embodiment of the present invention. The electrical device 1 includes a main housing 10 inside which there is housed a circuitry 20 for, for example, converting an alternating current supply to a direct current supply. For the sake of illustration, the power conversion circuitry 20 includes components which are vulnerable to moisture or dust deposit and is preferably enclosed within a moisture- or dust-free environment.

For the sake of completeness, the power conversion circuitry of the present preferred embodiment is connected between an electrical plug 30 for connecting to the 110V or 220V means supply or other suitable alternating current supply and a cable 40 for connecting to an external device such as a battery charger, mobile phone or other devices. The power conversion circuitry 20 is usually mounted on a PCB 21 and the pins of the electrical plug are connected to proximal locations on the PCB 21 generally because of the usual size limitation of this type of applications where compactness is of certain importance. The main housing 10 generally includes a first housing member 11 and a second housing member 12 which are generally made of a rigid, insulating and non-conductive material such as hard plastics. Examples of hard plastic materials suitable for forming the main housing include polypropylene, ABS, polycarbonate and alloys of ABS and polycarbonates. Of course, other appropriate hard plastics or other suitable materials can also be utilized to form the main housing 10.

In general, the first housing member 11 and the second housing member 12 are moulded to pre-determined forms so that when the first housing member 11 and the second housing member 12 are connected together along their corresponding edges, a hollow main housing providing an adequate hollow space for accommodating the circuitry 20 is formed.

To provide preliminary sealing along the corresponding edges, the corresponding edges between the first housing member 11 and the second housing member 12 are preferably overlapped and are then welded together by ultrasonic or other appropriate welding means. Of course, the corresponding edges of the first and second housing members can also be made to be snap-fittable so that they are snap-fitted before welding. However, it is well known that ultrasonic welding or welding in general is not entirely reliable for making water- or moisture-tight sealing, especially when there are comers or abrupt junctions. To improve the water- or moisture-tightness of the device, and since the major weakness will be along the corresponding edges 60 between the first housing member 11 and the second housing member 12, a thermoplastic material is then moulded onto the main housing 10 and along the corresponding edges 60 to provide further sealing. The thermoplastic material is preferably moulded as a band or a layer which is adhesively bonded to both the first housing member 11 and the second housing member 12.

In order to provide satisfactory sealing, this thermoplastic material should generally be non-permeable and is compatible with the material of the main housing which means the thermoplastic moulded layer can be securely bonded or adhered to the main housing 10 to ensure water- or moisture-tightness with reasonable durability and adhesive strength. For a main housing made of hard plastics such as ABS, polycarbonate or alloys of ABS and polycarbonate, thermoplastic elastomers such as Desmopan™ and Elastollan™, a thermoplastic polyurethane respectively from Bayer AG and BASF AG and Hylene™, a thermoplastic elastomer from Dupont, have been test as satisfactory to provide satisfactory bonding or adhesive characteristics with the rigid main housing suitable for the present application. Of course, other combinations of hard plastics for making the main housing and thermoplastics for sending can of course be used without loss of generality.

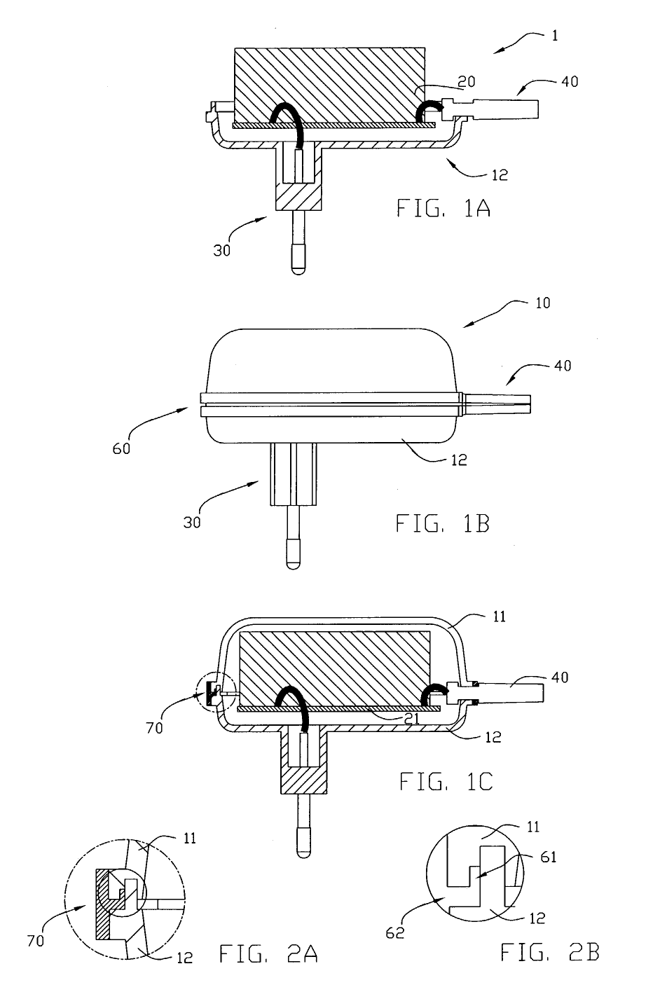

To further enhance the bonding or adhesion of the moulded thermoplastic sealing layer to the main housing, a bonding channel or groove 61 which generally extends along the corresponding peripheral edges of the first housing member 11 and the second housing member 12 and spanning the first housing member 11 and the second housing member 12 is formed as shown in FIG. 1C. This bonding channel or groove 61 can be formed, for example, by having a peripheral indentation provided along the bottom edge of the first housing member 11, that is, the edge correspondingly shaped to the upper edge of the second housing member 12. At the same time, the upper edge of the second housing member is provided with a peripherally extending protrusion having a thickness smaller than that of the corresponding indentation on the first housing member 11 so that an appropriate space defining the width of the bonding channel or groove 61 will be formed. To further enhance the bonding strength and to provide increased adhesion between the first housing member 11 and the second housing member 12, a further bonding channel 62 which extends generally at an angle to the bonding channel, which angle is preferably near 90°, is formed between the first and the second housing members. By having a bonding channel 61, 62 with an angular bending cross section, the moulded thermoplastic sealing layer 70 is generally hooked onto the main housing and will be well secured for improved durability and reliability. The electrical device with the moulded thermoplastic sealing layer can be seen as an illustration in FIG. 3.

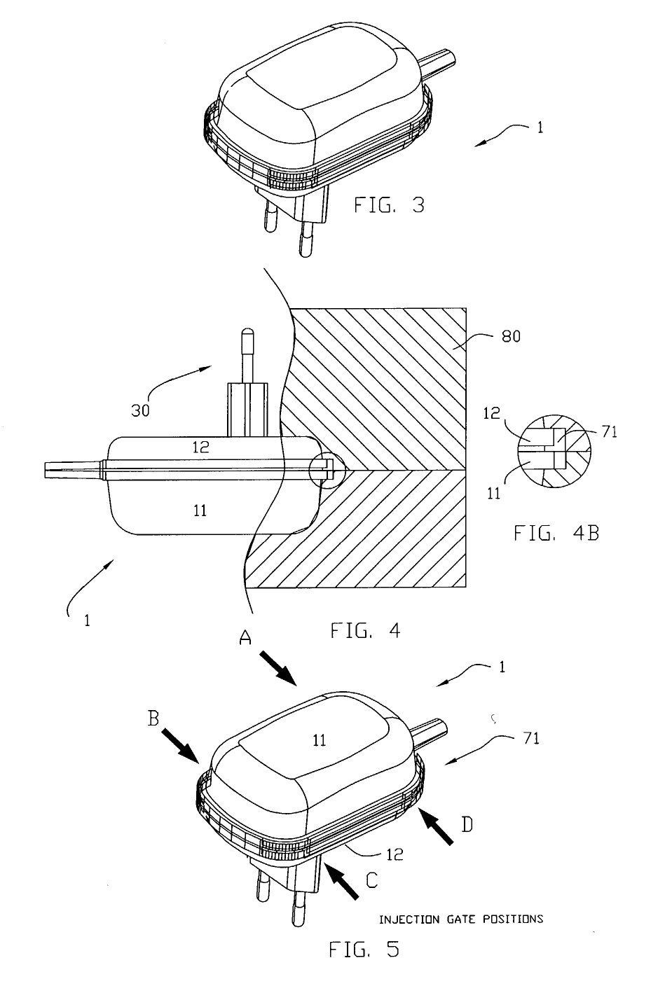

To mould the thermoplastic sealing material or, preferably, the thermoplastic elastomer, onto the main housing 10, the semi-assembled device of FIG. 1B is inserted into the moulding 80 for injection moulding. The enlarged view of FIG. 4B illustrates the shape or appearance of the moulded thermoplastic sealing layer defined between the moulding and the semi-assembled device.

Furthermore, in order to provide an even or aesthetically pleasing moulded sealing layer, multi-point injection is preferred to alleviate the unevenness due to the injection moulding process. For non-circular main housings, it is preferable that the injection points are generally distributed at the various diagonal ends for more balanced injections. For example, for a multi-point injection moulding, the combination of the injection points A & C or B & D will be desirable to enhance the visual characteristic of the moulded thermoplastic sealing layer.

Furthermore, the junction between the cable bushing and the main housing can also be sealed by the thermoplastic sealing material in the injection moulding process.

Thus, in order to mould the thermoplastic sealing layer to the main housing, the following process will generally be used:-

forming a first housing member and a second housing member,

forming the electrical connections and housing the connections within the main housing,

connecting the first and second housing members,

placing the connected first and second housing members into a mould,

moulding the layer of non-permeable thermoplastic to the corresponding edges of the main housing.

If multi-point injection moulding is utilized, sequential injection through generally diagonal injection point pairs are preferred to improve the surface condition of the sealing elastomer layer.

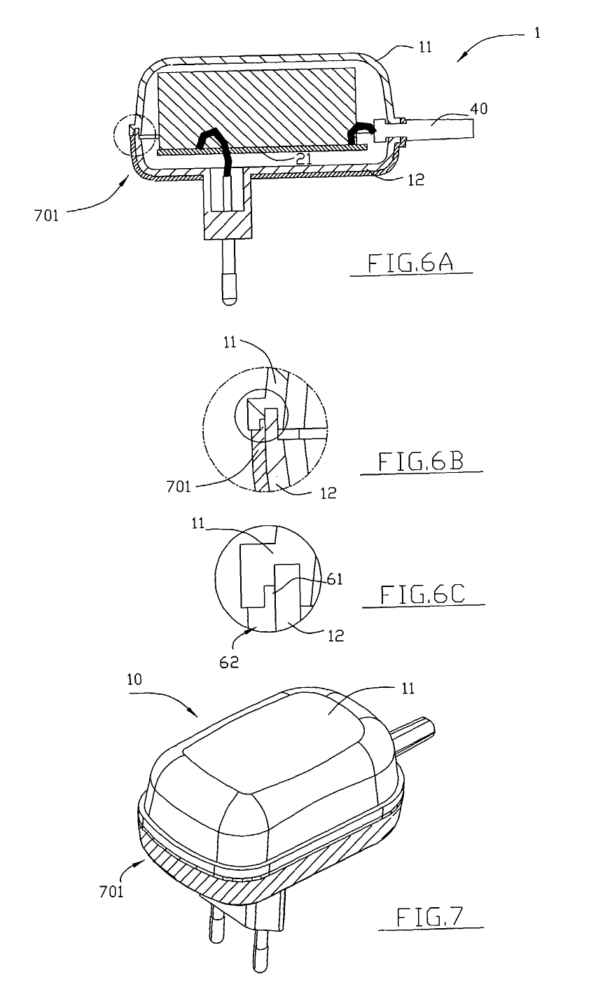

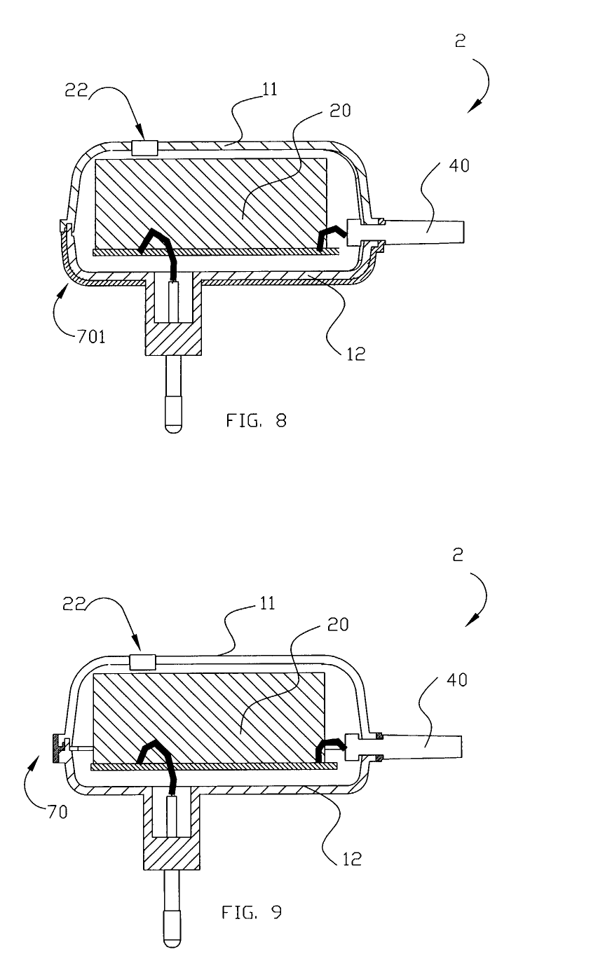

Referring to FIGS. 6A to 7, there is shown the electrical device 1 as described above but with a different manner for moulding the thermoplastic elastomer sealing layer 701 for illustrating a second preferred embodiment of the present invention. For the sake of brevity through this specification, common numerals will be used to illustrate parts which are substantially similar or having the same functions or purposes.

In this second preferred embodiment, the thermoplastic elastomer layer 701 is moulded onto the second housing member 12 with the upper edge of this thermoplastic elastomer layer filled inside the bonding channel 61 and the further bonding channel 62, thereby providing further adhesive bonding between the first housing member 11 and the second housing member 12 as well as completely sealing the corresponding edges between the first housing member 11 and the second housing member 12.

Referring to FIG. 8, there is shown another example of an electrical device 2 in the form of an ALCI or a GLCI plug for use with domestic appliances to provide protection against ground leakage or over current protection. In addition to the major components shown in FIG. 1C, this electrical device 2 includes an additional switch 22 for testing or resetting the operating states of the plug. In the preferred embodiment of FIG. 8, the thermoplastic sealing layer 701 is applied to the electrical device 2 in the manner described in relation to the electrical device 2 as described in FIGS. 6A to 7.

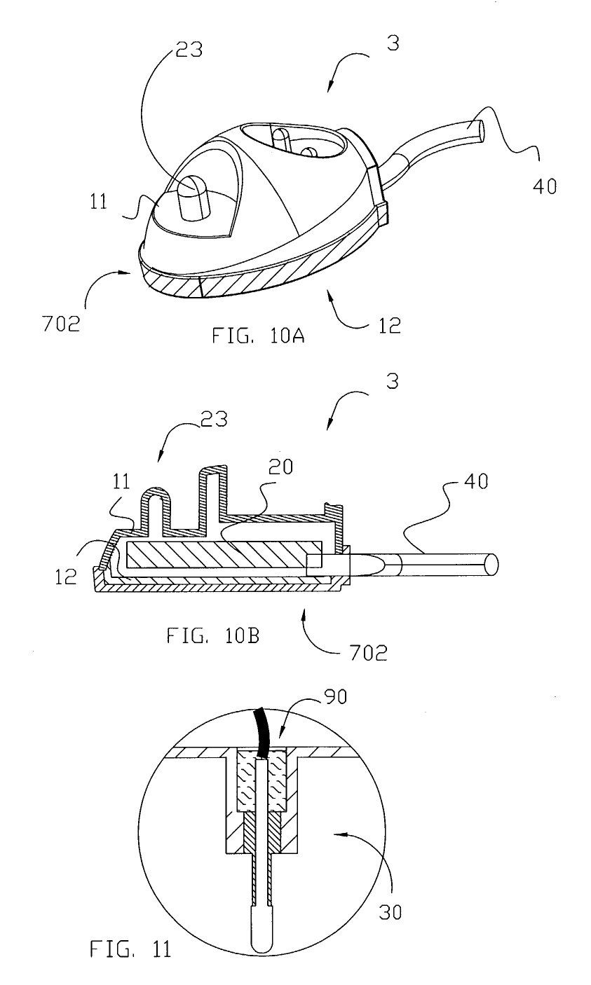

Referring to FIG. 9, the electrical device 2 of FIG. 8 is now applied with the thermoplastic elastomer sealing layer 70 moulded to the main housing 10 in a manner similar to that shown in FIGS. 1C to 5.

Referring to FIG. 10A, there is shown yet another example of an electrical device 3 in the form of a non-contact charging station, for example, a charger for cordless electric toothbrushes. This electrical device 3 generally includes the same basic components for the purpose of this invention and includes a support 23 for receiving an article to be charged. As such a charging station 3 is frequently used in humid or wet places such as bathrooms, effective sealing against moisture or water intrusion is important to ensure durability. FIGS. 10A and 10B illustrates the application of a thermoplastic elastomer sealing layer 702 in a manner similar to that described in FIG. 6A and FIG. 8 such that the thermoplastic elastomer layer generally covers the lower portion of the second housing member 12 as well as sealing the corresponding edges between the first housing member 11 and the second housing member 12, thereby also providing additional adhesive bonding between the first housing member 11 and the second housing member 12. Of course, the thermoplastic elastomer sealing layer can also be applied in a manner similar to that described in the first preferred embodiment.

FIG. 11 illustrates additional moisture sealing by applying resin coating to seal of the junction between the legs or pins of the plug and the hollow space inside the main housing 1.

Although the present invention has been explained with reference to examples of certain specific electrical devices, it will be understood that the present invention generally applies to cabled or non-cabled electrical devices requiring sealing against moisture or water intrusion. Examples of other suitable electrical device applications include electrical or electronic devices for outdoor, underwater or underground use.

While the present invention has been explained by reference to the preferred embodiments described above, it will be appreciated that the embodiments are only examples provided to illustrate the present invention and are not meant to be restrictive on the scope and spirit of the present invention. This invention should be determined from the general principles and spirit of the invention as described above. In particular, variations or modifications which are obvious or trivial to persons skilled in the art, as well as improvements made on the basis of the present invention, should be considered as falling within the scope and boundary of the present invention. Furthermore, while the present invention has been explained by reference to a power converter or a power adapter, it should be appreciated that the invention can apply, whether with or without modification, to other electric devices with an enclosing housing which required enhanced water- or moisture-tightness, regardless whether a plug or a cable will extend from the housing.

1. An electrical device including a main hollow housing inside which there are housed a plurality of electrical connections, said main housing includes at least a first and a second housing members which together form a hollow space for accommodating said connections, said first and second housing members being sealed and connected along their corresponding edges with a moulded layer of non-permeable thermoplastic material which is adhesive or bondable to said first and second housing of said main housing.

2. An electrical device according to claim 1, wherein a peripheral groove extending generally along said connected corresponding edges and spanning said first and second housing members is generally formed by co-operation between said first and said second housing members, said peripheral groove being generally filled with said non-permeable thermoplastic material for sealing.

3. An electrical device according to claim 2, wherein said thermoplastic material being a thermoplastic elastomer.

4. An electrical device according to claim 2, wherein said first and second housing members being made of hard thermoplastics.

5. An electrical device according to claim 2, wherein said first and second housing members being made of ABS, polycarbonate or an alloy of ABS and polycarbonate.

6. An electrical device according to claim 5, wherein said thermoplastic material for sealing being made either of Thermoplastic-urethane (TPU) or Thermoplastic Elastomer (TPE).

7. An electrical device according to claim 2, wherein said thermoplastic sealing material being applied on said main housing by injection moulding.

8. An electrical device according to claim 2, wherein said thermoplastic sealing material being applied on said main housing by in-mould or over-mould process.

9. An electrical device according to claim 2, wherein said device further includes a conductive plug extending outwardly from one of said housing members and a cable extending from a junction between said first and said second housing members.

10. An electrical device according to claim 9, wherein said junction between said cable and said main housing is sealed with a moulded layer of thermoplastic material.

11. An electrical device according to claim 10, wherein power supply circuit is connected between said cable and said conductive plug and is housed within said main housing.

12. An electrical device according to claim 11, wherein said power supply circuitry includes a transformer, a rectifying circuit, or a combination of both a transformer and a rectifying circuit.

13. An electrical device according to claim 2, wherein said first and said second housing members are connected by ultrasonic welding before the filling of said non-permeable thermoplastic sealing material along said corresponding edges.

14. A mould for moulding non-permeable thermoplastic material to the main housing of the device of claim 1 along said corresponding edges.

15. A mould according to claim 14, characterized in having a plurality of injection points distributed along locations opposite said corresponding edges.

16. A method or process of making an electrical device of claim 1, including the steps of:-
forming said electrical connections and housing said connections within said main housing,
connecting said first and second housing members,
placing said connected first and second housing members into a mould,
moulding said layer of non-permeable thermoplastic to said corresponding edges of said main housing.

17. A method or process of claim 16, wherein said first and said second housing members are connected by ultrasonic means.

18. A method or process of claim 16, wherein said mould includes a plurality of injection points distributed at locations corresponding and opposite to said corresponding edges of said main housing, each injection step utilizes two injection points on generally diagonally opposite sides of said main housing.
